(19) United States
(12) Patent Application Publication
(10) Pub. No.: US 2026/0164182 A1
(43) Pub. Date: Jun. 11, 2026

(54) MICRO-ELECTRO-MECHANICAL SYSTEMS TRANSDUCER WITH DEFLECTION CONSTRAINT

(71) Applicant: Knowles Electronics, LLC, Itasca, IL (US)

(72) Inventors: Shubham Shubham, Itasca, IL (US); Faisal Zaman, Itasca, IL (US); Yunfei Ma, Itasca, IL (US); Jen-I (Peter) Cheng, Itasca, IL (US); Michael Kuntzman, Itasca, IL (US); Michael Pedersen, Itasca, IL (US)

(73) Assignee: Knowles Electronics, LLC, Itasca, IL (US)

(21) Appl. No.: 18/974,274

(22) Filed: Dec. 9, 2024

(51) Int. Cl. H04R 7/26; B81B 3/00; H04R 7/04; H04R 7/20; H04R 19/04

(52) U.S. Cl. CPC H04R 7/26; B81B 3/001; B81B 3/0051; H04R 7/04; H04R 7/20; H04R 19/04; B81B 2201/0257; B81B 2203/0127; B81B 2203/0163; H04R 2201/003

(57) ABSTRACT

A Micro-Electro-Mechanical System (MEMS) die includes a substrate; a back plate mounted to the substrate and partially covering an aperture through the substrate; a diaphragm between the back plate and the substrate, the diaphragm comprising a central portion covering the aperture and an outer peripheral portion coupled to the substrate; a plurality of springs connecting the central portion of the diaphragm to the outer peripheral portion of the diaphragm, each spring located outwardly of the aperture; and a plurality of deflection limiters protruding from the back plate. The plurality of deflection limiters is located and configured to at least momentarily contact the diaphragm proximate the plurality of springs during operation of the MEMS die.

### FIELD OF THE DISCLOSURE

The present disclosure relates generally to Microelectromechanical Systems (MEMS) transducers, and more particularly to MEMS transducers comprising constrained diaphragms and deflection limiters.

### BACKGROUND

Microelectromechanical systems (MEMS) microphones are increasingly used in all manner of applications for their small size, low cost, and the ability to readily integrate them in host devices and systems. MEMS transducers are commonly used for detecting sound in wireless handsets, laptop computers, smart speakers, wireless earphones, headsets, appliances and automobiles, among a variety of other consumer and industrial goods and machinery.

MEMS microphones comprise a capacitive MEMS transducer connected to an electrical circuit for converting sound to electrical signals. Some capacitive MEMS transducers comprise a diaphragm including springs defined by slots in the diaphragm to facilitate deflection of the diaphragm. However, the springs are weak spots and tend to fail, particularly when the microphone is subject to high pressure events or shock. Thus, there is an ongoing need for improvements in MEMS transducers.

### BRIEF DESCRIPTION OF THE DRAWINGS

The foregoing and other features of the present disclosure will become more fully apparent from the following description and appended claims, taken in conjunction with the accompanying drawings. These drawings depict only several embodiments in accordance with the disclosure and are, therefore, not to be considered limiting of its scope.

FIG. 1 is a cross-sectional view of a representative MEMS transducer with diaphragm deflection limiters.

FIG. 2 is an enlarged partial perspective view of a representative diaphragm deflection limiter.

FIG. 3 is a partial plan view of a diaphragm showing where deflection limiters contact the diaphragm in a first generally circular pattern near the springs in accordance with a representative embodiment of the present disclosure.

FIG. 4 is a partial plan view of a diaphragm showing where deflection limiters contact the diaphragm in a second generally circular and denser pattern near the springs.

FIG. 5 is a partial plan view of a diaphragm showing where deflection limiters contact the diaphragm in a third generally circular multi-row pattern near the springs in accordance with a representative embodiment of the present disclosure.

FIG. 6 is a partial plan view of a diaphragm showing where deflection limiters contact the diaphragm in a fourth generally circular multi-row wavy pattern near the springs in accordance with a representative embodiment of the present disclosure.

FIG. 7 is a cross-sectional view of a MEMS transducer with deflection limiters contacting the diaphragm when biased in accordance with another representative embodiment of the present disclosure.

FIG. 8 is a cross-sectional view of the MEMS transducer of FIG. 7 under high acoustic pressure burst showing pressure from the diaphragm towards the back plate according to one embodiment.

FIG. 9 is a cross-sectional view of the MEMS microphone of FIG. 7 under high acoustic pressure burst showing pressure from the top of the diaphragm towards the back hole according to one embodiment.

FIG. 10 is a perspective view of a spring defined by one or more slots disposed in a diaphragm in accordance with a first representative embodiment of the present disclosure.

FIG. 11 is a perspective view of a spring defined by one or more slots disposed in a diaphragm in accordance with a second representative embodiment of the present disclosure.

FIG. 12 is a perspective view of a spring defined by one or more slots disposed in a diaphragm in accordance with a third representative embodiment of the present disclosure.

FIG. 13 is a partial plan view of a diaphragm having springs defined by circumferential slots according to one embodiment.

FIG. 14 is a partial plan view of a diaphragm having springs defined by circumferential slots having a wavy pattern according to one embodiment.

FIG. 15 is a partial plan view of a diaphragm having springs defined by circumferential and radial slots according to another embodiment.

FIG. 16 is a partial plan view of a diaphragm having springs defined by circumferential slots in multiple rows according to yet another embodiment.

FIG. 17 is a partial plan view of a diaphragm having springs defined by circumferential slots having smaller curves and a fin-like pattern according to another embodiment.

FIG. 18 is a partial plan view of a diaphragm having springs defined by circumferential slots and multiple radial slots arranged in alternate patterns according to yet another embodiment.

FIG. 19 is a partial plan view of a diaphragm having springs defined by circumferential slots having small curves in a fin-like pattern and radial slots according to one embodiment.

In the following detailed description, various embodiments are described with reference to the appended drawings. Those of ordinary skill in the art will appreciate that the drawings are illustrated for simplicity and clarity and therefore may not be drawn to scale and may not include well-known features, that the order of occurrence of actions or steps may be different than the order described or may be performed concurrently unless specified otherwise, and that the terms and expressions used herein have the meaning understood by those of ordinary skill in the art except where different meanings are attributed to them herein. Like reference numerals refer to like elements or components throughout. Like elements or components will therefore not necessarily be described in detail with respect to each figure.

### DETAILED DESCRIPTION

The present disclosure relates to a Micro-Electro-Mechanical System (MEMS) transducer (also referred to herein as a “MEMS die”) for use in a MEMS a microphone or other capacitive sensor. The MEMS die is a capacitive device comprising a substrate, a fixed back plate mounted to the substrate and partially covering an aperture through the substrate, and a diaphragm between the back plate and the substrate. The diaphragm comprises a central portion covering the aperture and an outer peripheral portion coupled to the substrate. A plurality of springs, comprising one or more slots located in the diaphragm, connect the central portion of the diaphragm to the outer peripheral portion of the diaphragm. Each spring is located outwardly of the aperture. In operation, the diaphragm moves with respect to the back plate in response to acoustic energy passing through the aperture. Movement of the diaphragm in relation to the back plate causes a capacitance between the diaphragm and back plate to vary. The change in capacitance can be measured and converted into a corresponding electrical signal by an electrical circuit coupled to the MEMS die. The springs reduce stress and stiffness of the diaphragm.

The MEMS die further comprises a plurality of deflection limiters protruding from the back plate. The deflection limiters are located and configured to at least momentarily contact the diaphragm during operation of the MEMS die. The deflection limiters limit deflection of the diaphragm near spring regions to reduce localized stress at the springs and thereby prevent device failure during high burst events (e.g., dropping the MEMS die). The deflection limiters can also limit deflection of other portions of the diaphragm.

The present disclosure minimizes stress efficiently at/around the springs through precise arrangement of deflection limiters near the springs. The deflection limiters can be arranged on the back plate in a generally circular pattern on a fixed or varying radius from a center of the back plate. Deflection limiters can be arranged in multiple rows with varying levels of proximity to the springs. Deflection limiters can be arranged to contact the diaphragm with varying densities. Advantageously, deflection limiters can be precisely arranged and configured to limit the diaphragm deflection to approximately 1 um (micrometer) or less; or may limit the diaphragm deflection to a fraction of the total operating gap between the back plate and the diaphragm. Reducing the distance between deflection limiter row and inner spring row, preferably to approximately 10 um or less has been found to greatly improve the effectiveness of deflection limiters of the present disclosure. The density of deflection limiters can be fine-tuned to maximize the effectiveness of the deflection limiters. In addition, further improvements can be realized by adjusting the pattern of the deflection limiters around the springs, for example by arranging the deflection limiters in a wavy pattern. Overall, the present disclosure provides for robustness, improvement, and ingress protection, as the springs improve compliance, sensitivity, and signal-to-noise ratio (SNR) of microphones comprising the MEMS transducer, while deflection limiters protect against failure of the MEMS microphone when subject to excessive acoustic energy (e.g., air bursts and shock events).

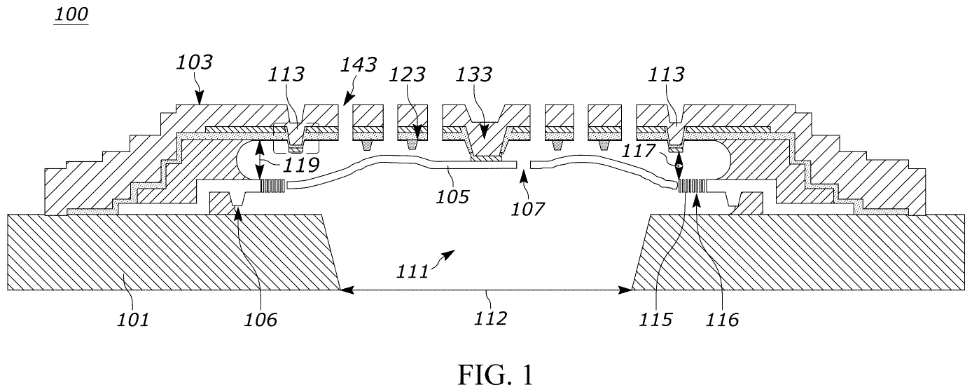

In FIG. 1, a MEMS transducer 100 comprises a substrate 101, a back plate 103 mounted to substrate 101, and a diaphragm 105 between back plate 103 and substrate 101. Backplate 103 is perforated and partially covers an aperture 111 through substrate 101. Diaphragm 105 comprises a central portion covering the aperture 111 and a round back hole 112 of the substrate. Diaphragm 105 comprises an outer peripheral portion coupled to substrate 101. Back plate 103 is mounted to substrate 101. A plurality of deflection limiters 113 protrude from back plate 103. A plurality of springs 115 connect the central portion of diaphragm 105 to the outer peripheral portion of diaphragm 105. Each spring 115 is located outwardly of aperture 111. The plurality of deflection limiters 113 are located and configured to contact diaphragm 105 in response to a transient air burst or shock during operation of the MEMS transducer 100.

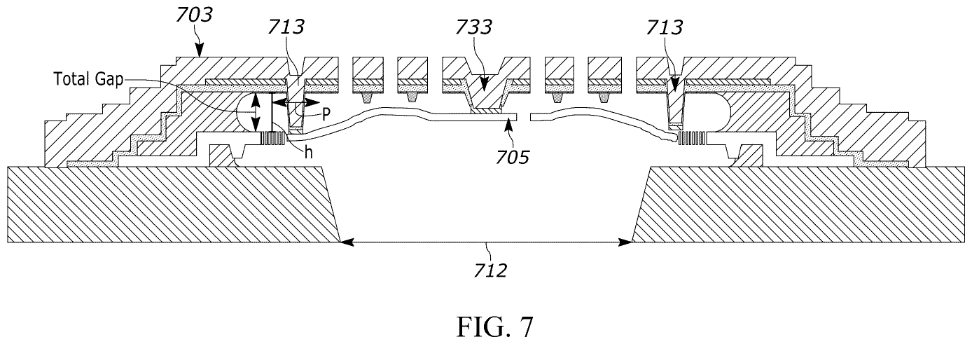

In FIG. 1, deflection limiters 113 constrain deflection of diaphragm 105 near springs 115. Deflection limiters 113 are spaced apart from diaphragm 105 when diaphragm 105 is biased toward back plate 103 and MEMS transducer 100 is not subject to excessive acoustic energy. Deflection of diaphragm 105 toward back plate 103 is limited by plurality of deflection limiters 113 when MEMS transducer 100 is subject to excessive acoustic energy. Deflection limiters 113 that contact diaphragm 105 are arranged on back plate 103 in a generally circular pattern on at least one radius from a center of back plate 103. In alternative embodiments, deflection limiters contact diaphragm when the diaphragm is biased towards backplate (see e.g., FIG. 7). This embodiment is described in more detail below with reference to FIG. 7.

When diaphragm 105 is operating under normal conditions, diaphragm 105 flexes due to a difference in air pressure in MEMS transducer 100. If diaphragm 105 flexes too much, such as during high pressure shock events, diaphragm 105 can encounter mechanical failure. This is especially true of diaphragms 105 that include springs therein. In addition, particle and water ingress also becomes an issue if the slots experience large opening under high pressure. Deflection limiters 113 prevent diaphragm 105 from flexing excessively during these events by coming into contact (i.e., physical contact) with diaphragm 105, thereby lessening the chance that diaphragm 105 (e.g., the springs) will suffer mechanical failure. Deflection limiters 113 preferably include a controlled remaining gap 117 between back plate 103 and diaphragm 105, and the controlled remaining gap 117 is preferably a fraction of the total operating gap 119 between diaphragm 105 and back plate 103.

Still referring to FIG. 1, MEMS transducer 100 further comprises over pressure stops (OPSs) 123 protruding from back plate 103 and located inwardly of deflection limiters 113. Deflection of the central portion of diaphragm 105 towards back plate 103 is limited by contact with OPSs 123 when the MEMS transducer 100 is subject to excessive acoustic energy. OPSs 123 prevent stiction of diaphragm 105 to back plate 103 after it collapses, when the electrostatic pulling force exceeds the mechanical stiffness of diaphragm 105; or, mechanically, when the acoustic pressure is high enough to make diaphragm 105 collapse to back plate 103. A post 133 protrudes from center of back plate 103 and is configured to contact the central portion of diaphragm 105 when diaphragm 105 is biased toward back plate 103. Post 133 is in contact with diaphragm 105 during normal operation of MEMS transducer 100.

The diaphragm is a small, thin silicon layer having a plurality of springs that connect a central section of the diaphragm with an outer section of the diaphragm. In FIG. 1, a plurality of springs 115 are defined by a plurality of slots in the diaphragm 105. A first end portion of each spring 115 is connected to the central portion of diaphragm 105 and a second end portion of each spring 115 is connected to the outer peripheral portion of diaphragm 105. At least some of the springs 115 are oriented non-perpendicular to a perimeter of diaphragm 105.The slots create at least one in-plane spring 116 connecting a central section of diaphragm 105 with an outer section of diaphragm 105.

In FIG. 1, diaphragm 105 includes protrusions 106, protruding from diaphragm 105 towards substrate 101. Protrusions 106 may also be called anti-stiction bumps as they are configured to reduce the risk of stiction between diaphragm 105 and substrate 101. Diaphragm 105 includes a vent opening 107, which together with springs 115 provides for barometric and low acoustic frequency pressure relief of diaphragm 105. Back plate 103 includes a plurality of acoustic holes 143, which serve to reduce acoustic damping associated with the operating gap 119 between diaphragm 105 and back plate 103.

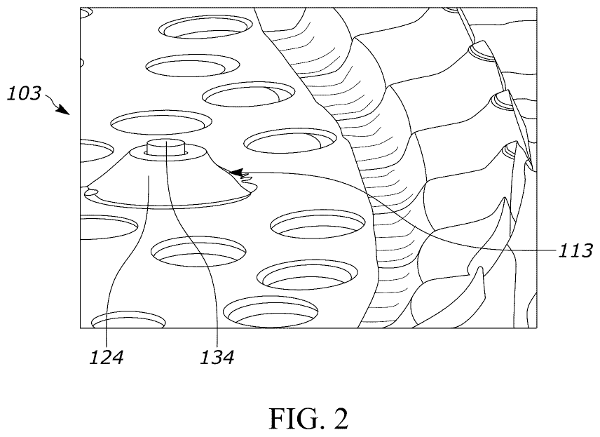

FIG. 2 is an enlarged, perspective view of deflection limiter 113 (back plate 103 flipped-up). Deflection limiter 113 is tapered and has a base portion 124 and a tip portion 134. Base portion 124 is preferably wider than tip portion 134.

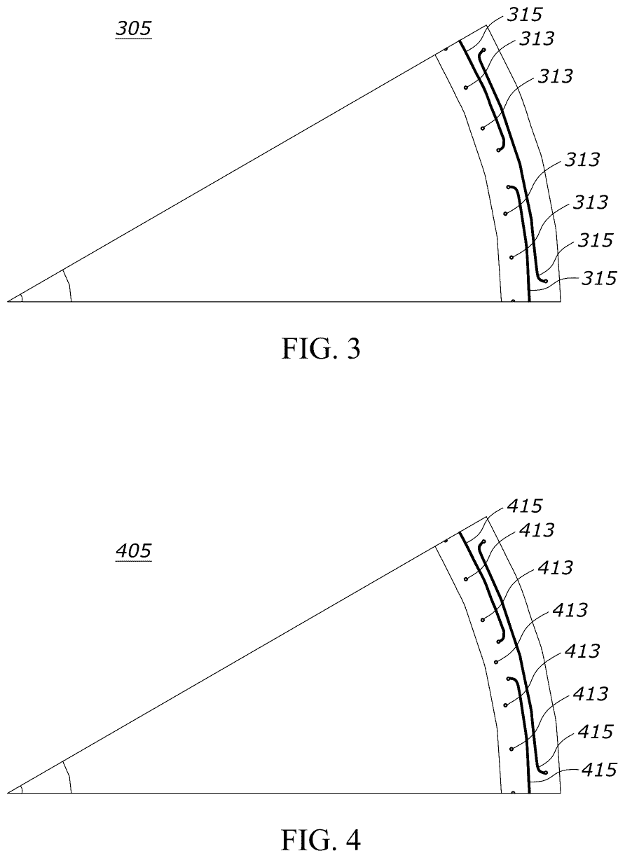

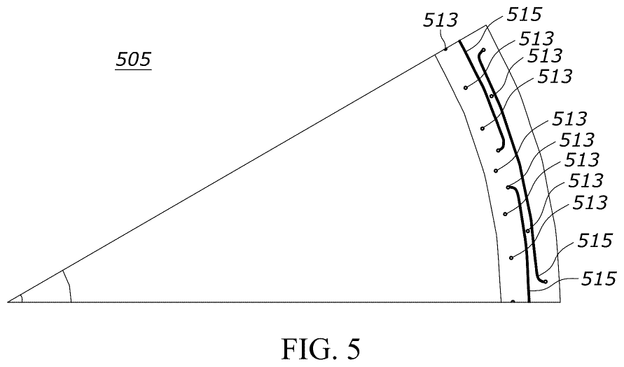

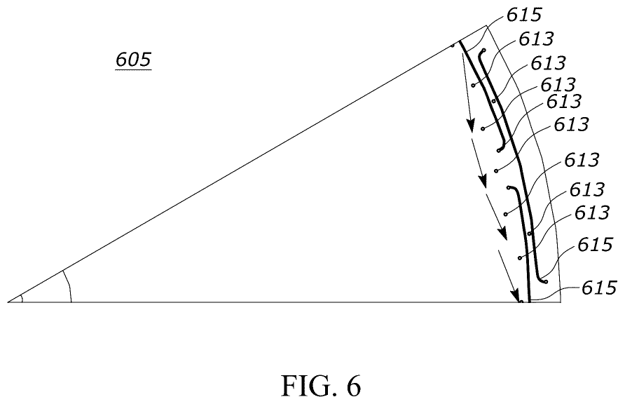

FIGS. 3-6 depict alternative arrangements of wherein deflection limiters contact the diaphragm near the springs. The deflection limiters are arranged to protrude from the back plate in correspondence with the contact points on the diaphragm. Similar elements to those shown in FIG. 1 are included in FIGS. 3-6 and these descriptions will not be repeated here. Like features of the alternative embodiments have similar reference numbers preceded by a number corresponding to the respective figure number in place of the number “1”. In FIG. 3, deflection limiters are arranged in a generally circular pattern on a radius from a center of back plate (not shown) and are arranged to contact the diaphragm proximate to slots 315 defining the springs in diaphragm 105. Approximately 60 deflection limiters (DLs) 313 are arranged to contact the diaphragm proximate the slots 315 defining the springs, approximately 20 um from slots 315. FIG. 4 illustrates a higher density deflection limiter contact points 413 on the diaphragm (e.g., 72 DLs). FIG. 5 illustrates two concentric rows of DLs contact points 513 with one high density DL inner row and one low density DL outer row located on springs. Inner row of DL contact points 513 is closer (e.g., 10 um) to slots 515 than the contact points in FIGS. 3 and 4. FIG. 6 illustrates DLs contact points 613 arranged on the diaphragm in concentric rows with inner row in a wavy pattern near slots 615.

Deflection limiters are effective in preventing large openings of springs during high pressure events. Deflection limiters allow for small deflection around the spring region when arranged in a unique pattern as disclosed herein. Deflection limiters therefore prevent high stress concentration around springs and prevents mechanical failure. In addition, deflection limiters assist in ingress protection by limiting the out-of-plane deflection, and opening, of the diaphragm near the springs.

In FIG. 7, deflection limiters 713 are configured to contact diaphragm 705 when diaphragm 705 is biased towards back plate 703 during normal operation (as compared to the embodiment depicted in FIG. 1 where deflection limiters 113 are spaced apart from diaphragm 105 when diaphragm 105 is biased towards back plate 103 during normal operation). Similar elements to those shown in FIG. 1 are included in FIGS. 7-9 and these descriptions will not be repeated here. Deflection limiters 713 can be the same height, h, as the post 733. Position, p, of deflection limiter 713 is such that deflection of diaphragm 705 can contact deflection limiter 713 even if height, h, is not the same as the post 733. This is possible if the deflection limiter 713 is located in the region where deflection of diaphragm 705 is large by virtue of the spring design (i.e., deflection is equivalent to the gap under deflection limiter 713) to make contact.

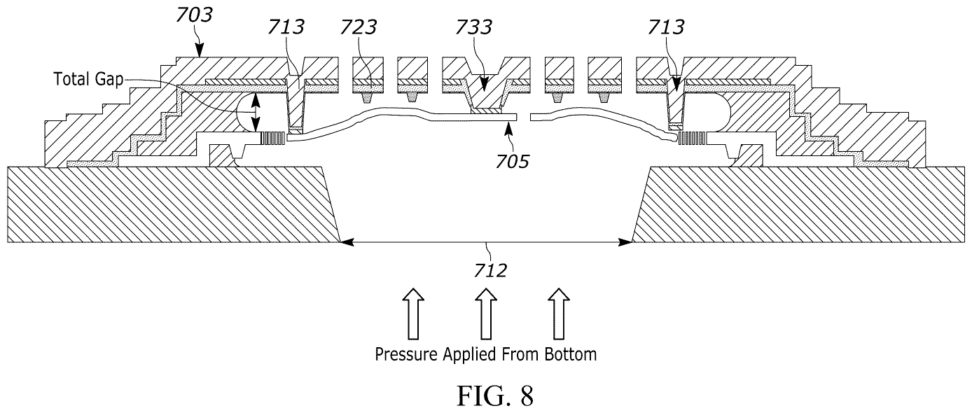

In FIG. 8, a high acoustic pressure burst event has occurred at MEMS transducer 700 of FIG. 7. It can be seen in FIG. 8 that deflection of the central portion of diaphragm 705 toward back plate 703 is limited by contact with OPSs 723 when MEMS transducer 700 is subject to excessive acoustic energy. Diaphragm 705 contacts back plate 703 at post 733, deflection limiters 713 and OPSs 723. Back plate 703 acts as a support for diaphragm 705 in a forward pressure event (pressure from bottom of diaphragm 705 toward back plate 703).

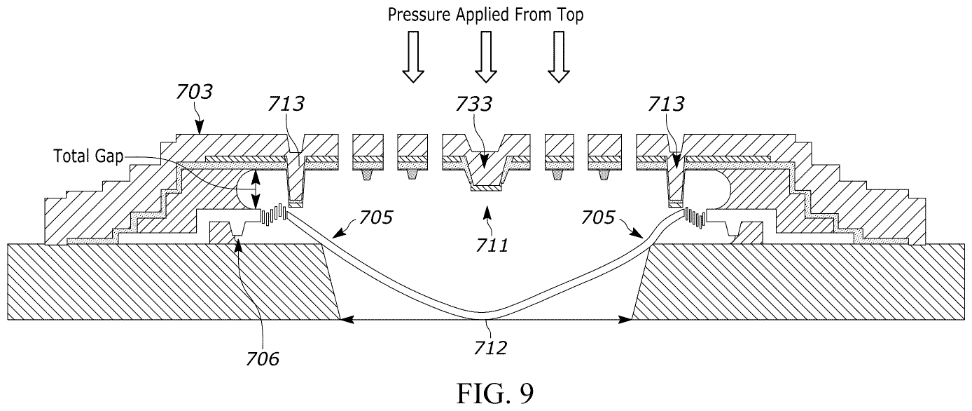

In FIG. 9, pressure is applied from the top of diaphragm 705 toward aperture 711. It can be seen in FIG. 9 that diaphragm 705 contacts substrate 701 and extends into the round back hole 712. Protrusions 706 on diaphragm 705 also contact substrate 701 during this high pressure event. Referring still to FIG. 9, deflection limiters 713 contact diaphragm 705 under reverse pressure to limit spring movement and reduce stress at the spring region. This is possible if the deflection is largely by virtue of the slot/spring design. It is apparent from FIGS. 8 and 9 that MEMS die of the present disclosure provides substrate 701 limiting deflection of the central portion of diaphragm 705 away from back plate 703, at the same time deflection limiters 713 limit deflection of the peripheral portion of diaphragm 705 toward back plate 703 when MEMS transducer 700 is subject to excessive acoustic energy.

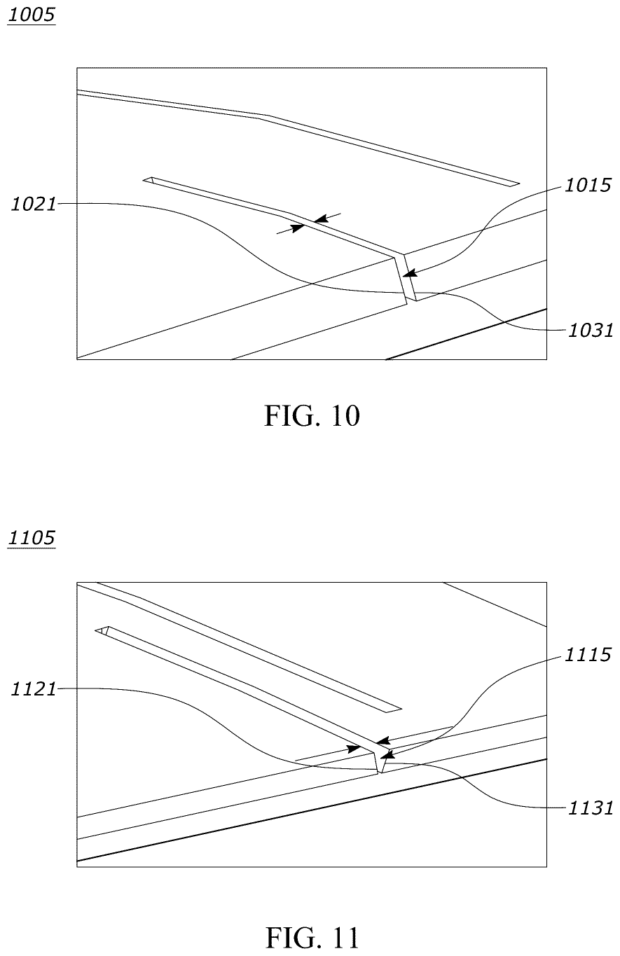

Springs can be defined by slots in diaphragm. FIGS. 10-18 depict alternative slot arrangements. Similar elements to those shown in FIG. 1 are included in FIGS. 10-19 and these descriptions will not be repeated here. In FIG. 10, slot has a narrow (e.g., 0.5 um width) straight shape. First side 1021 and a second side 1031 are parallel and define a long narrow channel 1015.

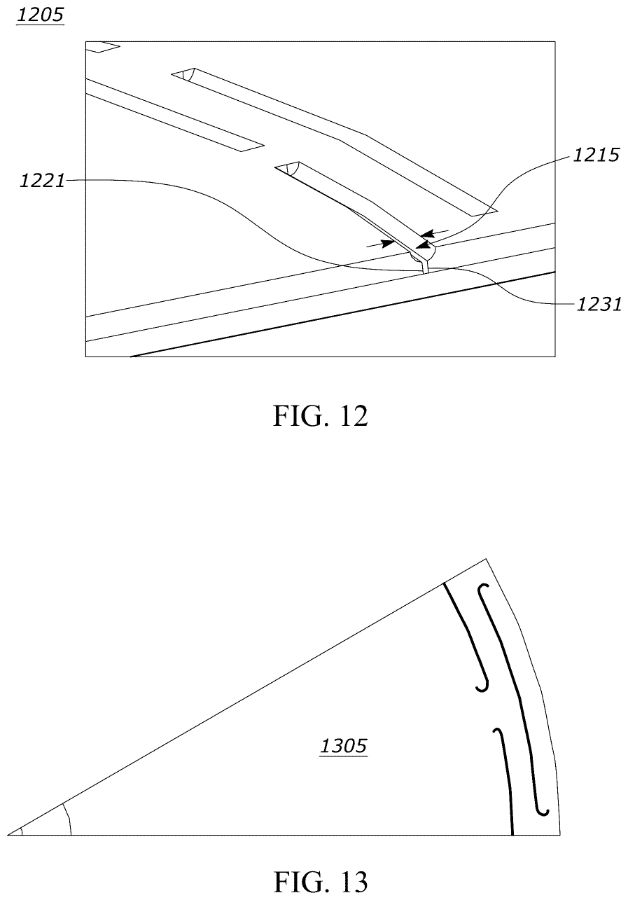

In alternative embodiments, slots have a larger gap at a side of diaphragm facing back plate than a gap at a side of diaphragm facing away from back plate. In FIG. 11, first side 1121 and second side 1131 of slot are angled, defining a tapered shape channel 1115. In FIG. 12, slot has a wine glass shaped (or Y-shaped) channel 1215. First side 1221 and second side 1231 each have a straight section and a concave section.

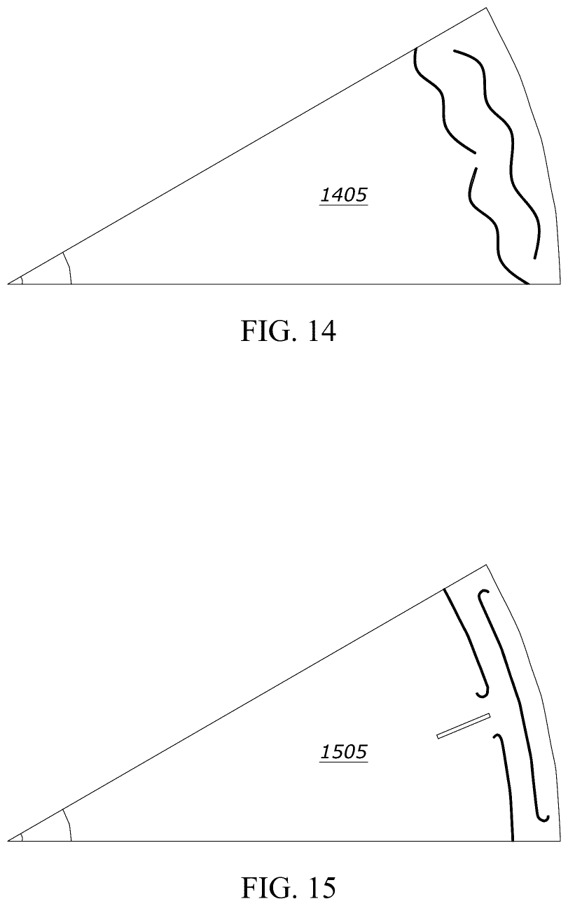

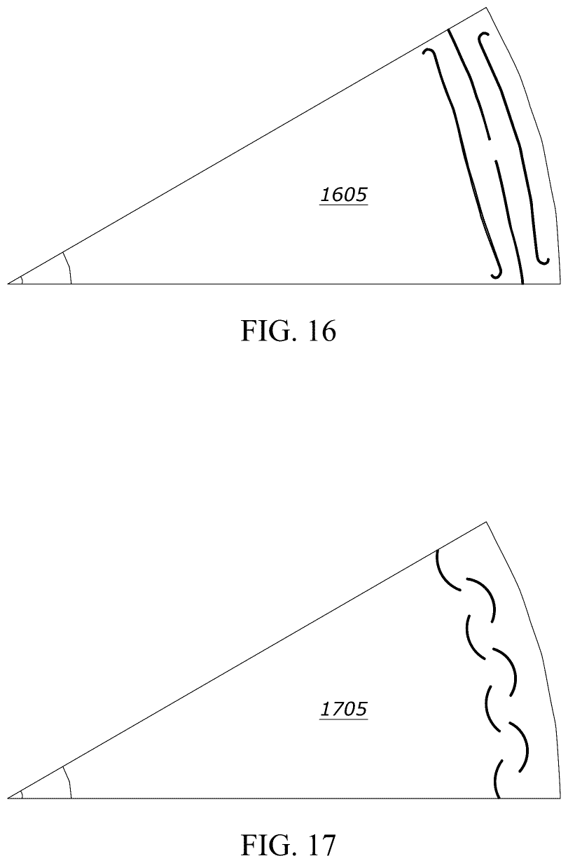

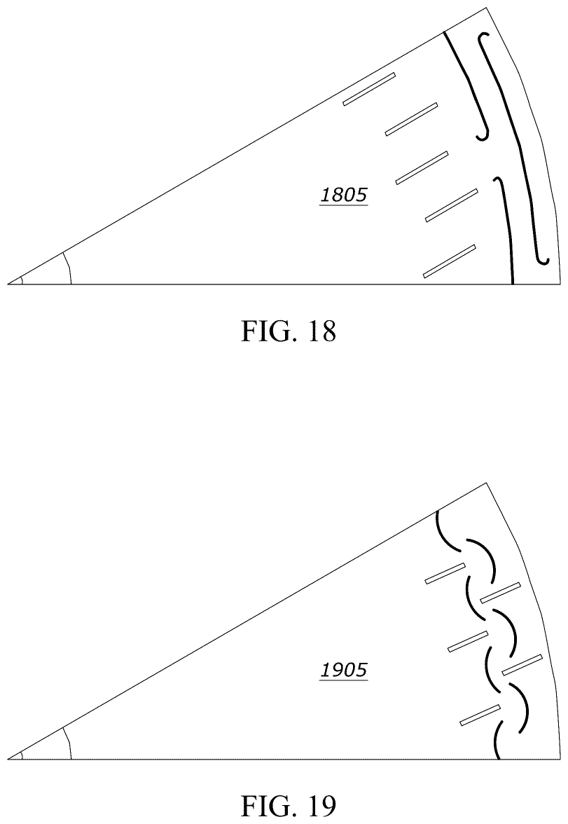

In FIG. 13, circumferential slots are depicted. Slot corners are weak spots where cracks/tears can begin to form. FIG. 14 illustrates circumferential slots with a wavy pattern. FIG. 15 illustrates circumferential and radial slots. FIG. 16 illustrates circumferential slots with multiple rows. FIG. 17 has circumferential slots with small curves, like fin patterns. FIG. 18 has circumferential slots and multiple radial slots arranged in alternate patterns. FIG. 19 has circumferential slots with small curves, like fin patterns, and multiple radial slots arranged in between the fin patterns.

While the disclosure and what is presently considered to be the best mode thereof has been described in a manner establishing possession and enabling those of ordinary skill in the art to make and use the same, it will be understood and appreciated that there are many equivalents to the select embodiments described herein and that myriad modifications and variations may be made thereto without departing from the scope and spirit of the disclosure, which is to be limited not by the embodiments described herein but by the appended claims and their equivalents. For example, various components of the embodiments may be interchanged, added, or substituted in the other embodiments.

What is claimed is:

1. A Microelectromechanical Systems (MEMS) transducer comprising:
a substrate;
a back plate mounted to the substrate and partially covering an aperture through the substrate;
a diaphragm between the back plate and the substrate, the diaphragm comprising a central portion covering the aperture and an outer peripheral portion coupled to the substrate;
a plurality of springs connecting the central portion of the diaphragm to the outer peripheral portion of the diaphragm, each spring located outwardly of the aperture; and
a plurality of deflection limiters protruding from the back plate,
wherein the plurality of deflection limiters is located and configured to at least momentarily contact the diaphragm proximate the plurality of springs during operation of the MEMS transducer.

2. The MEMS transducer of claim 1, the plurality of deflection limiters spaced apart from the diaphragm when the diaphragm is biased toward the back plate and the MEMS transducer is not subject to excessive acoustic energy, wherein deflection of the diaphragm toward the back plate is limited by the plurality of deflection limiters when the MEMS transducer is subject to excessive acoustic energy.

3. The MEMS transducer of claim 2, wherein deflection limiters that contact the diaphragm are arranged on the back plate in a generally circular pattern on at least one radius from a center of the back plate.

4. The MEMS transducer of claim 1 further comprising overpressure stops protruding from the back plate and located inwardly of the plurality of deflection limiters, wherein the plurality of deflection limiters contact the diaphragm when the diaphragm is biased toward the back plate, and deflection of the central portion of the diaphragm toward the back plate is limited by the overpressure stops when the MEMS transducer is subject to excessive acoustic energy.

5. The MEMS transducer of claim 1, wherein the plurality of springs are defined by a plurality of slots in the diaphragm, a first end portion of each spring is connected to the central portion of the diaphragm and a second end portion of each spring is connected to the outer peripheral portion of the diaphragm, and at least some of the springs are oriented non-perpendicular to a perimeter of the diaphragm.

6. The MEMS transducer of claim 5, wherein at least some slots comprise a larger gap at a side of the diaphragm facing the back plate than a gap at a side of the diaphragm facing away from the back plate.

7. The MEMS transducer of claim 1, wherein the substrate limits deflection of the central portion of the diaphragm away from the back plate when the MEMS transducer is subject to excessive acoustic energy.

8. The MEMS transducer of claim 7, wherein the plurality of deflection limiters limit deflection of the outer peripheral portion of the diaphragm toward the back plate at the same time the substrate limits deflection of the diaphragm away from the back plate.

9. A Microelectromechanical Systems (MEMS) die for a microphone, the MEMS die comprising:
a substrate;
a perforated back plate mounted to the substrate and covering an aperture through the substrate;
a diaphragm between the back plate and the substrate, the diaphragm comprising a central portion covering the aperture and an outer peripheral portion coupled to the substrate, the central portion of the diaphragm coupled to the outer peripheral portion of the diaphragm by a plurality of springs located outwardly of the aperture;
a post protruding from the back plate and configured to contact the central portion of the diaphragm when the diaphragm is biased toward the back plate; and
a plurality of deflection limiters protruding from the back plate and spaced apart from the diaphragm when the diaphragm is biased toward the back plate and when the MEMS die is not subject to excessive acoustic energy,
wherein deflection of the diaphragm toward the back plate is limited by contact with the plurality of deflection limiters when the MEMS die is subject to excessive acoustic energy.

10. The MEMS die of claim 9, wherein the plurality of deflection limiters is located on the back plate outwardly of the aperture and configured to contact the diaphragm when the MEMS die is subject to excessive acoustic energy.

11. The MEMS die of claim 10 further comprising overpressure stops protruding from the back plate inwardly of the plurality of deflection limiters, wherein deflection of the central portion of the diaphragm toward the back plate is limited by contact with the overpressure stops when the MEMS die is subject to excessive acoustic energy.

12. The MEMS die of claim 10, wherein the plurality of springs are defined by a plurality of slots in the diaphragm, a first end portion of each spring is connected to the central portion of the diaphragm and a second end portion of each spring is connected to the outer peripheral portion of the diaphragm, and at least some of the springs are oriented non-perpendicular to a perimeter of the diaphragm.

13. The MEMS die of claim 12, wherein at least some slots comprise a larger gap at a side of the diaphragm facing the back plate than a gap at a side of the diaphragm facing away from the back plate.

14. The MEMS die of claim 12, wherein deflection limiters that contact the diaphragm are arranged on the back plate in a generally circular pattern on at least one radius from a center of the back plate.

15. The MEMS die of claim 12, wherein the substrate limits deflection of the central portion of the diaphragm away from the back plate at the same time the plurality of deflection limiters limit deflection of the peripheral portion of the diaphragm toward the back plate when the MEMS die is subject to excessive acoustic energy.

16. A Microelectromechanical Systems (MEMS) die for a microphone, the MEMS die comprising:
a substrate;
a perforated back plate mounted to the substrate and covering an aperture through the substrate;
a diaphragm between the back plate and the substrate, the diaphragm comprising a central portion covering the aperture and an outer peripheral portion coupled to the substrate, the central portion of the diaphragm coupled to the outer peripheral portion of the diaphragm by a plurality of springs located outwardly of the aperture;
a post protruding from the back plate and configured to contact the central portion of the diaphragm when the diaphragm is biased toward the back plate;
a plurality of deflection limiters protruding from the back plate and configured to contact the diaphragm when the diaphragm is biased toward the back plate; and
overpressure stops protruding from the back plate and located inwardly of the plurality of deflection limiters,
wherein deflection of the central portion of the diaphragm toward the back plate is limited by contact with the overpressure stops when the MEMS die is subject to excessive acoustic energy.

17. The MEMS die of claim 16, wherein the plurality of deflection limiters is located on the back plate to contact the diaphragm outwardly of the aperture.

18. The MEMS die of claim 17, wherein the plurality of springs are defined by a plurality of slots in the diaphragm, a first end portion of each spring is connected to the central portion of the diaphragm and a second end portion of each spring is connected to the outer peripheral portion of the diaphragm, and at least some of the springs are oriented non-perpendicular to a perimeter of the diaphragm.

19. The MEMS die of claim 18, wherein at least some slots comprise a larger gap at a side of the diaphragm facing the back plate than a gap at a side of the diaphragm facing away from the back plate.

20. The MEMS die of claim 18, wherein the substrate limits deflection of the central portion of the diaphragm away from the back plate at the same time the plurality of deflection limiters limit deflection of the peripheral portion of the diaphragm toward the back plate when the MEMS die is subject to excessive acoustic energy.
